(19) United States
(12) Patent Application Publication
(10) Pub. No.: US 2026/0130244 A1
(43) Pub. Date: May 7, 2026

(54) INTEGRATED CIRCUIT DEVICE WITH MULTI-CONDUCTOR VIA

(71) Applicant: Advanced Micro Devices, Inc., Santa Clara, CA (US)

(72) Inventors: Huajun CHEN, Shanghai (CN); Xuming HAN, Shanghai (CN); Xinwu SHAO, Shanghai (CN)

(21) Appl. No.: 18/939,280

(22) Filed: Nov. 6, 2024

(51) Int. Cl. H01L 23/498; H01L 23/00

(52) U.S. Cl. CPC H10W 70/635; H10W 70/65; H10W 90/724

(57) ABSTRACT

Described herein are an integrated circuit (IC) device mounting board, and an IC device, both of which having one or more multi-conductor vias. Also described herein are methods for fabricating an IC device mounting board having multi-conductor vias, and methods for operating IC devices having multi-conductor vias. The multi-conductor vias include separate conductive segments formed within a single via that allow any one of data signal, power and ground to be conducted on any one of the segments. Additionally, any one or more or even all of the conductive segments may be floating. The multi-conductor vias enables fewer vias to be utilized for a given number of contact pads, allowing for increased interconnect density.

### TECHNICAL FIELD

Embodiments of the invention generally relate to integrated circuit (IC) devices having multi-conductor vias, and methods for fabricating and using the same.

### BACKGROUND

With the development of integrated circuit (IC) chip designs, the number of ball grid array (BGA) pins is increasing as chips employ higher density circuitry across ever smaller nodes. As the number of BGA pins increases, the spacing between pins is getting smaller and smaller, while the density of routings on printed circuit boards (PCBs) is getting larger and larger. Thus, allocating sufficient space on a PCB to form reliable BGA interfaces and associated routings is becoming increasingly challenging.

Current PCB technology requires that each signal pin be associated with a unique via to provide a signal, power or ground interconnection. The space required to form the vias impede efficient fan-out configurations and current input of the signal lines. As a result, the next generation PCB designs will have ever increasing difficulty in meeting design requirements for higher density and larger power supply capacity of larger currents due, in part, by current limits on BGA size reduction.

Therefore, there is a need for an improved PCB and other IC device mounting boards that accommodates increased connection density as compared to conventional designs.

### SUMMARY

Disclosed herein are electronic devices and components that utilize multi-conductor vias, along with methods for fabricating and using the same. Examples include an integrated circuit (IC) device mounting board, and an IC device, both of which having one or more multi-conductor vias. Also described herein are methods for fabricating an IC device mounting board having multi-conductor vias, and methods for operating IC devices having multi-conductor vias. The multi-conductor vias include separate conductive segments formed within a single via that allow any one of data signal, power and ground to be conducted on any one of the segments. Additionally, any one or more or even all of the conductive segments may be floating. The multi-conductor vias enables fewer vias to be utilized for a given number of contact pads, allowing for increased interconnect density. Some non-limiting examples of IC device mounting boards include interposers, package substrates, printed circuit boards, and the like.

In one example, an integrated circuit (IC) device mounting board is provided that includes a first via formed through at least a portion of the support board. The first via includes a first conductive segment disposed on a sidewall of the first via and a second conductive segment disposed on the sidewall of the first via. The first and second conductive segments forming separate electrical signal paths through the first via. The support board also includes a first contact pad formed on a first side of the support board and electrically coupled to the first conductive segment, and a second contact pad formed on the first side of the support board and electrically coupled to the second conductive segment.

In another example, an integrated circuit (IC) device mounting board is provided that includes a support board having a first side and a second side. A plurality of contact pads including Y number of contact pads are formed on the first side of the support board. A plurality of vias having in-via conductors are connected to the plurality of contact pads. A number of the plurality of contact pads Y is greater than a number of the plurality of vias.

In another example, an integrated circuit (IC) device is provided that includes an integrated circuit (IC) die and an IC device mounting board. The IC die has at least a first contact pad and a second contact pad disposed on a first surface. The IC device mounting board has a first via formed in a first side. The IC die is mounted on the first side of the IC device mounting board. The IC device mounting board includes a first conductive segment disposed on a sidewall of the first via and a second conductive segment disposed on the sidewall of the first via. The first conductive segment is coupled to the first contact pad of the IC die and the second conductive segment is coupled to the second contact pad of the IC die.

In another example, an integrated circuit (IC) device is provided that includes an integrated circuit (IC) die and an IC device mounting board. The IC die is mounted on a first side of the IC device mounting board. The IC die includes at least a first contact pad and a second contact pad disposed on a first surface. The IC device mounting board has a first via formed in the first side. The IC device mounting board includes a support board having a first side and a second side, a plurality of contact pads including Y number of contact pads formed on the first side of the support board, and a plurality of vias formed in the support board. A number of the plurality of contact pads Y is greater than a number of the plurality of vias. At least a first contact pad and a second contact pad of the support board are coupled to the first and second contact pads of the IC die by separate in-via conductors disposed in a first via of the plurality of vias.

In yet another example, a method for fabricating an integrated circuit (IC) device mounting board is provided. The method includes forming a via at least partially through a support board having a first side and a second side, and forming a plurality conductive segments on a sidewall of the via. Each conductive segment is coupled to a unique one of a plurality of signal contact pads disposed on a first side of the support board.

In yet another example, a method for operating an integrated circuit (IC) device is provided. The method includes transmitting a first signal through a first via formed through at least a portion of an IC device mounting board to one or more integrated circuit devices mounted on the IC device mounting board; and transmitting a second signal through the first via formed through at least a portion of the IC device mounting board to the one or more integrated circuit devices mounted on the IC device mounting board. The first and second signals are conducted through the first via on separate conductive paths.

In still another example, an electronic plug is provided. The electronic plug includes a plurality of prongs extending from a housing, at least one of the prongs including separate conductive segments. Each conductive segment is connected to a separate wire. The separate wire exiting the housing forming a cable.

### BRIEF DESCRIPTION OF THE DRAWINGS

FIG. 1 depicts an electronic device having one or more components that includes a multi-conductor via.

FIG. 2 depicts another electronic device having one or more components that includes a multi-conductor via.

FIG. 3 is a partial sectional view of an IC device mounting board illustrating a multi-conductor via.

FIG. 4A is a schematic top view of one example of a multi-conductor via having a plurality of conductive segments.

FIG. 4B is a schematic top view of another example of a multi-conductor via having a plurality of conductive segments.

FIGS. 5A-5B depict various distributions of power, ground and signal that may be transmitted through a multi-conductor via having three conductive segments.

FIGS. 6A-6B are schematic top views of other examples of multi-conductor vias having a plurality of conductive segments.

FIGS. 7A-7B are schematic top views of other examples of multi-conductor vias having a plurality of conductive segments.

FIG. 8 is a schematic top view of an IC device mounting board illustrating one example of an arrangement of signal transmissions through multi-conductor vias.

FIGS. 9A-9C are schematic top views of one example of a multi-conductor via during different stages of fabrication.

FIGS. 10A-10D are schematic top views of another example of a multi-conductor via during different stages of fabrication.

FIG. 11 is a flow diagram of a method for fabricating a multi-conductor via, according to one example.

FIG. 12 is a flow diagram of a method for operating an electronic device that has a multi-conductor via, according to one example.

FIG. 13 is a plan view of a cable having a plug with pins configured to mate with multi-conductor vias formed in an IC device mounting board or other device.

FIG. 14 is a simplified schematic view of the plug of the cable illustrating one of the pins of the plug illustrated in FIG. 13.

FIG. 15 is a simplified schematic view of one of the pins of the plug illustrated in FIG. 13.

FIGS. 16-17 are isometric and sectional views of a chip package having a plurality of multi-conductor pins configured to mate with multi-conductor vias formed in an IC device mounting board or other device.

FIG. 18 is a partial top schematic view of one of the multi-conductor pins of the chip package illustrated in FIGS. 16-17.

FIG. 19 is a simplified schematic view of one of the multi-conductor pins of the chip package illustrated in FIGS. 16-17.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Described herein are an integrated circuit (IC) device mounting board and an IC device, both of which having one or more multi-conductor vias. Also described herein are methods for fabricating an IC device mounting board having multi-conductor vias, and methods for operating IC devices having multi-conductor vias. The multi-conductor vias include separate conductive segments formed within a single via that allow any one of data signal, power and ground to be conducted on any one of the segments. Additionally, any one or more or even all of the conductive segments may be floating. The multi-conductor vias enables fewer vias to be utilized for a given number of contact pads, allowing for increased interconnect density. The space saved by using the multi-conductor via enables a greater number of signal routing and provides a stronger power supply as metal layers used for power delivery have less holes per power supply pin. Some non-limiting examples of IC device mounting boards include interposers, package substrates, printed circuit boards, and the like. Additionally, the additional space provided by the multi-conductor vias allows for ball grid array (BGA) layouts to be optimized to make the area of the BGA smaller with the same performance as compared to conventional designs.

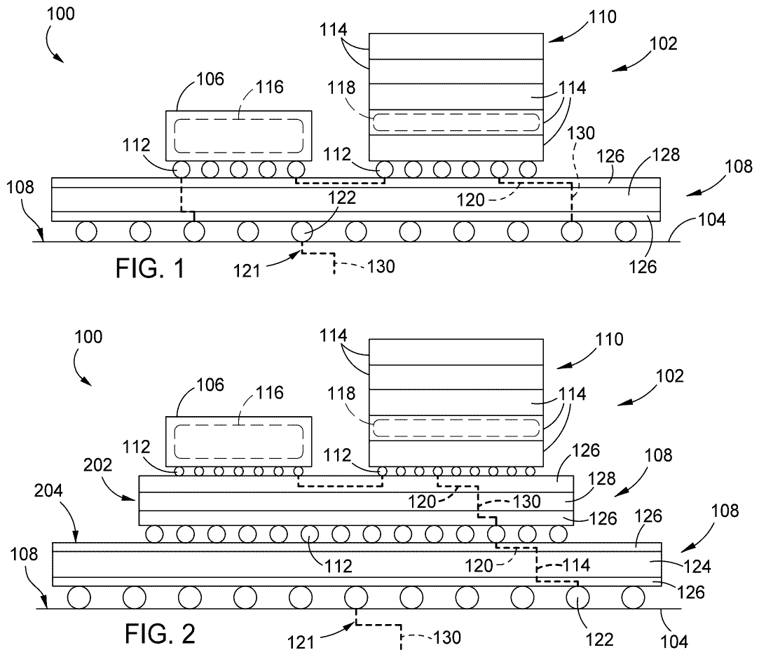

Turning now to FIG. 1, a schematic sectional view of an electronic device 100 having one or more components that includes a multi-conductor via is illustrated. The electronic device 100 includes at least one integrated circuit (IC) die 106. The IC die 106 is part of a chip package 102. The chip package 102 is mounted to an integrated circuit (IC) device mounting board 108, shown in FIG. 1 as a printed circuit board (PCB) 104, for example by use of solder balls 122 or other suitable technique. The chip package 102 also includes at least one IC device mounting board 108 to which the IC die 106 is mounted. In the example depicted in FIG. 1, the IC device mounting board 108 is configured as a package substrate. Alternatively as shown in FIG. 2, two IC device mounting boards 108 may be utilized within the chip package 102, one configured as a package substrate 204 while the other configured as an interposer 202.

Continuing to refer to FIG. 1, the IC die 106 of the chip package 102 includes functional circuitry 116. The functional circuitry 116 of the IC die 106 is connected by solder interconnects 112, such as micro bumps, or other suitable technique to the routing 120 of the underlying IC device mounting board 108. The functional circuitry 116 of the IC die 106 may include central processing unit (CPU) cores. As such, the IC die 106 may be referred to as a CPU die or CPU chiplet. The functional circuitry of the IC die 106 may also include System Management Unit (SMU) that is configured to monitor thermal and power conditions and adjust power and cooling to keep the IC die 106 functioning as within specifications. The functional circuitry of the IC die 106 may also include Dynamic Function eXchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In another example, the functional circuitry 116 of the IC die 106 includes accelerated compute cores. As such, the IC die 106 may be referred to as an accelerator die or accelerator chiplet. The IC die 106 may also be referred to as a graphic processing unit (GPU) die or GPU chiplet. The accelerated compute cores contained in the functional circuitry 116 of the IC die 106 generally include math engine circuitry. The math engine circuitry is generally designed for task specific computing, such as used data center computing, high performance computing and AI/ML computing. Along with the accelerated compute cores, functional circuitry 116 of the IC die 106 may also include SMU circuitry and DFX circuitry.

When one or more additional IC dies 106 are present in the chip package, the functional circuitry 116 the IC die 106 and additional IC dies 106 may be the same or different. For example, a first IC die 106 may include accelerated compute cores, while the second IC die 106 includes CPU cores. The additional IC dies 106, when present in the compute die stack, may include CPU cores and/or an accelerated compute cores. The one or more additional IC dies 106 may be vertically stacked on the IC die 106 and/or stacked laterally with the IC die 106.

Optionally, the one or more IC dies 106 of the chip package 102 may be paired with a memory stack 110, for example, configuring the chip package 102 as a high bandwidth memory (HBM) device. The memory stack 110 includes one or more memory IC dies 114.

The memory stack 110 is generally mounted on the IC device mounting board 108 adjacent the IC die 106 using solder interconnects 112 or other suitable technique. In the example depicted in FIG. 1, one or more memory stacks 110 are directly connected to the IC die 106 by the routing 120 formed in the IC device mounting board 108 underlying the dies 106 and memory stack 110. The memory dies 114 within the memory stack 110 can be interconnect via solder interconnect, via hybrid bonding, or other suitable technique. The memory dies 114 have functional circuitry 118 in the form of volatile memory, such as static random-access memory (SRAM), dynamic random-access memory (DRAM) or other suitable volatile memory type. Optionally, one or more of the memory dies 114 of the memory stack 110 may be non-volatile memory, such as ferroelectric random-access memory (FeRAM) and magnetoresistive random-access memory (MRAM) or other suitable non-volatile memory type. The functional circuitry 118 of the memory dies 114 of the memory stack 110 may be configured to have the same or different type of memory.

In one example, the bottom memory die 114 of the memory stack 110 is configured as a buffer die, having I/O circuitry. In another example, the bottom memory die 114 of the memory stack 110 is configured as a volatile or non-volatile memory die 114. The number of memory dies 114 within the memory stack 110 may range from 2 to as many as desired. In one example, the number of memory dies 114 within the memory stack 110 is 4 to about 16.

As discussed above, at least one or more of the components of the electronic device 100 includes one or more multi-conductor vias 130. Components of the electronic device 100 that may include the one or more multi-conductor vias 130 include the IC device mounting boards 108. For example, an IC device mounting board 108 configured as a PCB 104 may include routing 121 that includes one or more multi-conductor vias 130. In another example, an IC device mounting board 108 configured as an interposer 202 may include one or more build-up layers 126 and a support board 124 (e.g., a core) in which the routing 120 is formed, with some of the routing 120 connected to multi-conductor vias 130 formed through the support board 124. In still another example, an IC device mounting board 108 configured as a package substrate 204 may include one or more build-up layers 126 and a support board 124 (e.g., a core) in which the routing 120 is formed, with some of the routing 120 connected to multi-conductor vias 130 formed through the support board 124. The multi-conductor vias 130 may be in any one or any combination of the interposer 202, package substrate 204, and PCB 104.

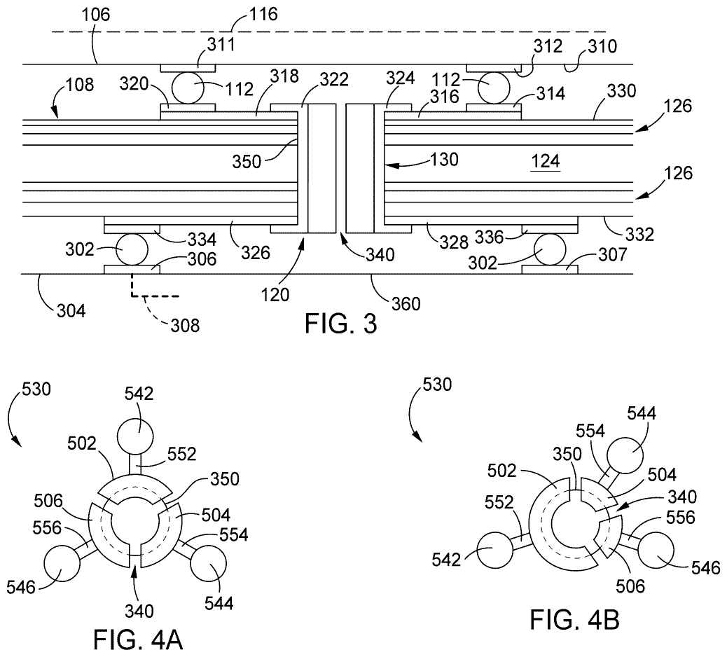

FIG. 3 is a side schematic view of one example of one of the multi-conductor vias 130 formed through the IC device mounting board 108. The IC device mounting board 108 is illustrated in FIG. 3 as a package substrate 204 having the IC die 106 mounted directly thereon, but may alternatively be either an interposer 202, a PCB 104 or the like. Although one multi-conductor via 130 is shown in FIG. 3, it is to be appreciated that a single IC device mounting board 108 can have hundreds to thousands or more multi-conductor vias 130. Each multi-conductor via 130 includes a plurality of electrically isolated conductive segments. Although 2 conductive segments 322, 324 are shown in FIG. 3, the number of conductive segments formed through a single multi-conductor via 130 may be 3, 4, 5, 6 or more conductive segments as needed or as limited by space or design constrains.

The IC device mounting board 108 depicted in FIG. 3 has a top surface 330 and a bottom surface 332. The top surface 330 faces a bottom surface 310 of the IC die 106. The top surface 330 includes at least two contact pads 314, 320. The first contact pad 314 is connected by one of the solder interconnects 112 to a contact pad 312 that resides on the bottom surface 310 of the IC die 106. The contact pad 312 is connected to the functional circuitry 116 of the IC die 106. The first contact pad 314 is connected by a trace 316 to a first conductive segment 324 that is part of the multi-conductor via 130 formed at least through the top surface 330 of the IC device mounting board 108. The trace 316 is generally part of the build-up layers 126 formed on the support board 124 of the IC device mounting board 108. The build-up layers 126 generally include a plurality of patterned metal layers separated by layers of dielectric material. The patterned metal layers (and trace 316) form part of the routing 120 through the IC device mounting board 108.

Similarly, the second contact pad 320 is connected by one of the solder interconnects 112 to a contact pad 311 that resides on the bottom surface 310 of the IC die 106. The contact pad 311 is also connected to the functional circuitry 116 of the IC die 106. The second contact pad 320 is connected by a trace 318 to a second conductive segment 322 that is part of the multi-conductor via 130. The first and second conductive segments 322, 324 generally extend along a hole 350 formed in the top surface 330 and support board 124 of the IC device mounting board 108. The trace 318 is similar to the trace 316 described above, and forms part of the routing 120 through the IC device mounting board 108.

The bottom surface 332 of the IC device mounting board 108 faces a top surface 304 of the IC device mounting board 360 that underlies the bottom surface 332 of the IC device mounting board 108 in which the multi-conductor via 130 shown in FIG. 3 resides. In FIG. 3, the IC device mounting board 108 is an interposer 202 or a package substrate 204, while the IC device mounting board 360 is a package substrate 204 or PCB 104.

Continuing to refer to FIG. 3, the bottom surface 332 of the IC device mounting board 108 includes at least two contact pads 334, 336. The first contact pad 336 is connected by one of the solder interconnects 302 to a contact pad 307 of the IC device mounting board 360 that resides below the bottom surface 332 of the IC device mounting board 108. The contact pad 307 is connected to the routing 308 of the IC device mounting board 360. The routing 308 may optionally include one or more multi-conductor vias 130. The contact pad 336 is connected by a trace 328 to the first conductive segment 324 of the multi-conductor via 130. The trace 328 is generally part of the build-up layers 126 formed below the support board 124 of the IC device mounting board 108. The trace 328 form part of the routing 120 through the IC device mounting board 108.

Similarly, the second contact pad 334 is connected by one of the solder interconnects 302 to a contact pad 306 that resides on the top surface 304 of the IC device mounting board 360 that underlies the bottom surface 332 of the IC device mounting board 108. The contact pad 334 is connected by a trace 326 to the second conductive segment 322 of the multi-conductor via 130.

The conductive segments 322, 324 of the multi-conductor via 130 are separated by a gap 340, which allows the conductive segments 322, 324 of the multi-conductor via 130 to be electrically isolated from each other. The gap 340 may be an air gap or a gap filled with an electrically insulating material that is suitable for electrically isolating the conductive segments 322, 324 of the multi-conductor via 130 from each other. For example, one of the conductive segments 322, 324 can carry power while, the other of conductive segments 322, 324 carries ground or data signals. In another example, one of the conductive segments 322, 324 can carry a data signal, while the other of conductive segments 322, 324 carries ground or power. In still another example, the conductive segments 322, 324 can carry separate data signals.

As multiple conductive segments 322, 324 are disposed through a common multi-conductor via 130, the number of contact pads 320, 314 exceeds the number of vias 130 needed in a single IC device mounting board 108. In other words, a number Y of the contact pads 320, 314 disposed on one side of the IC device mounting board 108 is greater than a number X of the plurality of vias 130. In some examples, a ratio of Y/X is 2:1, 3:1, 4:1 or even greater than 5:1. By extension, the number of separate conductive segments disposed through a single multi-conductor via 130 may also have a ratio of 2:1, 3:1, 4:1 or even greater than 5:1.

Thus, a smaller number of vias are needed to accommodate a greater number of contact pads as compared to conventional designs. In the example depicted in FIG. 3, a single multi-conductor via 130 can accommodate at least two sets of contact pads 320, 314. As the number of electrically isolated conductive segments disposed in a common multi-conductor via is only limited by space and/or design constrains, an IC device mounting board 108 may have one half, a third, a quarter or even less vias per contact pads. This enables increased contact pad density. Additionally, fewer vias allows for more metal to be present in the metal layers comprising power delivery networks within the IC device mounting board 108, advantageously providing a stronger power supply and improved power delivery.

FIG. 4A is a schematic top view of another example of a multi-conductor via 530 having a plurality of conductive segments, shown as conductive segments 502, 504, 506, formed in an IC device mounting board 108. The multi-conductor via 530 may be used in place of one or more of the multi-conductor vias 130 described above within the electronic device 100.

The multi-conductor via 530 is generally configured similar to the multi-conductor via 130 described above, except with an additional conductive segment 506 disposed through a common hole 350 formed in the IC device mounting board 108. The first conductive segment 502 is coupled to a first contact pad 542 by a first trace 552. The second conductive segment 504 is coupled to a second contact pad 544 by a second trace 554. The third conductive segment 506 is coupled to a third contact pad 546 by a third trace 556. The conductive segments 502, 504, 506 may have the same or different sectional area. In the example depicted in FIG. 4A, the sectional area of the conductive segments 502, 504, 506 are the same. In an example depicted in FIG. 4B, the sectional area of at least two of conductive segments 502, 504, 506 are different. For example in FIG. 4B, the sectional area of the first conductive segment 502 is greater than the sectional area of at least the second conductive segment 504, while the sectional area of the second conductive segment 504 is equal to or greater than the sectional area of the third conductive segment 506. Having different sectional areas may be beneficial for allocating more sectional area of conductive segments for one application, such as power delivery, as compared to other conductive segments carrying ground and/or data signals.

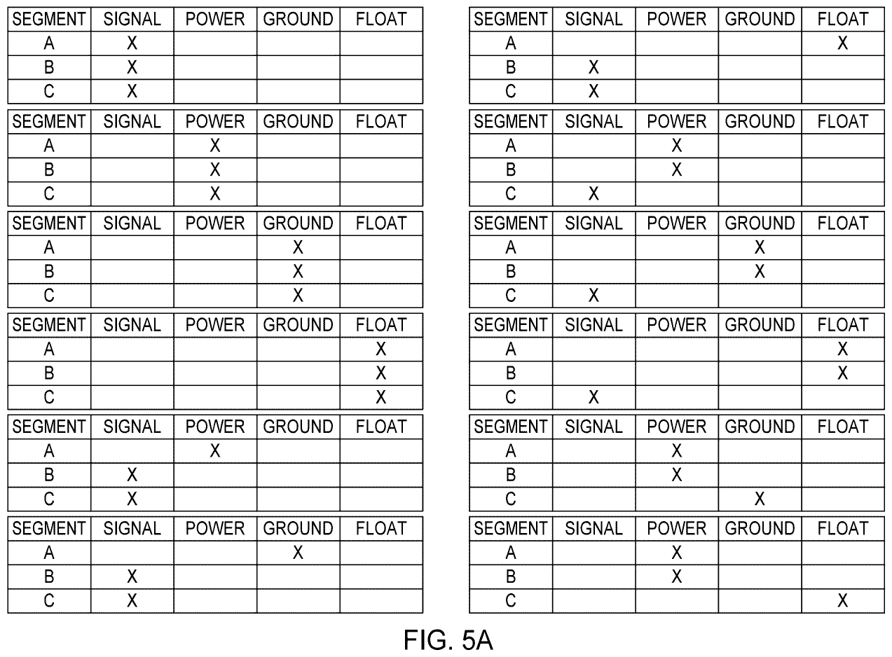

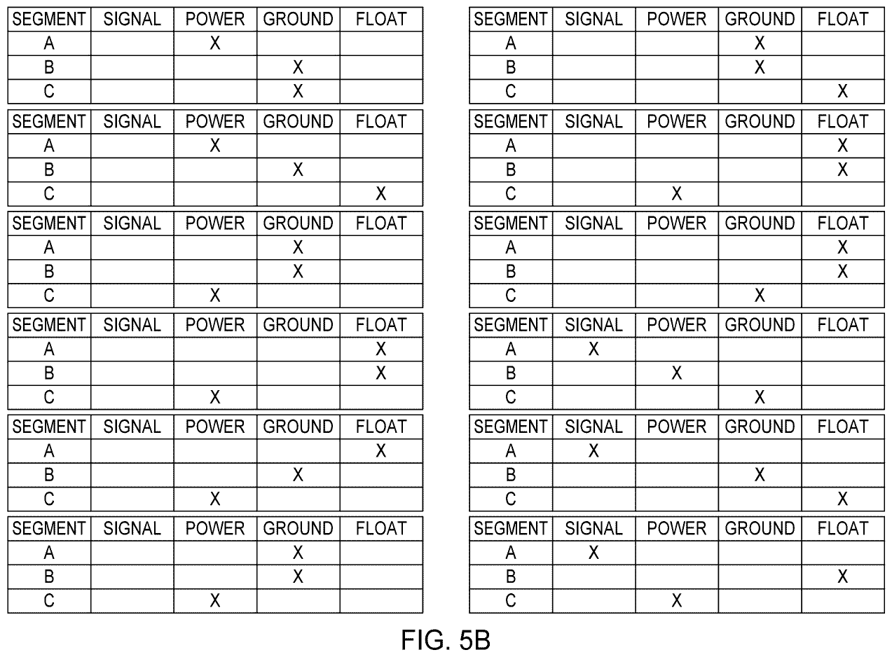

Continuing to refer to FIG. 4A, the conductive segments 502, 504, 506 are electrically isolated by a gap 340, which enable any combinations data signals, power and ground to be transmitted through a single multi-conductor via 530. FIGS. 5A-5B depict various distributions of power, ground and data signals that may be transmitted through the multi-conductor via 530 having three conductive segments 502, 504, 506. In the tables illustrated in FIGS. 5A-5B, conductive segment 502 is represented as conductive segment A, conductive segment 504 is represented as conductive segment B, and conductive segment 506 is represented as conductive segment C.

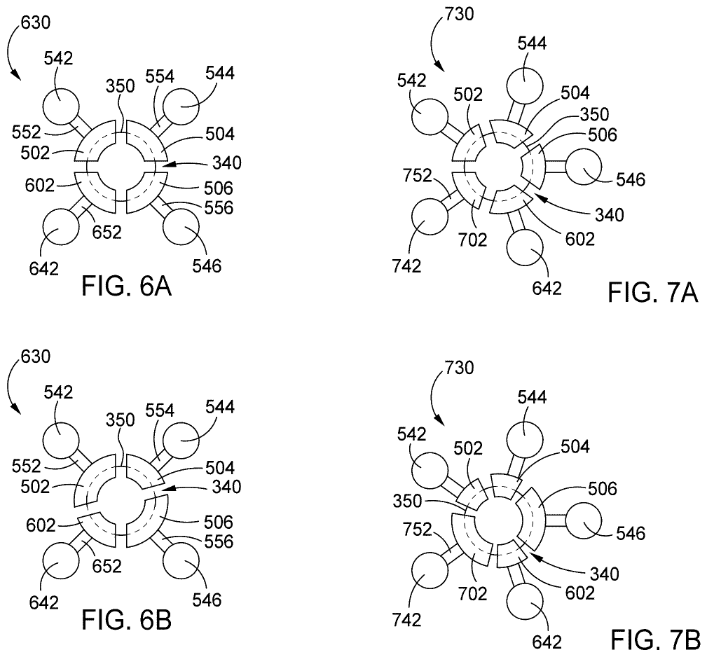

FIGS. 6A-6B are schematic top view of other examples of multi-conductor vias having a plurality of conductive segments. In the example depicted in FIG. 6, a multi-conductor via 630 is illustrated having 4 conductive segments 502, 504, 506, 602. The conductive segments 502, 504, 506, 602 may have the same sectional area, or one or more of the conductive segments 502, 504, 506, 602 may have a second area different than one or more of the other conductive segments 502, 504, 506, 602.

The multi-conductor via 630 illustrated in FIG. 6A is generally the same as the multi-conductor via 530 described above, except with an additional conductive segment 602 disposed through a common hole 350 formed in the IC device mounting board 108. The first, second and third conductive segments 502, 504, 506 are coupled to the first, second and third contact pads 542, 544, 546 by the first, second and third traces 552, 554, 556 as described with reference to FIG. 4A. Similarly, the fourth conductive segment 602 is coupled to a fourth contact pad 642 by a fourth trace 652.

The conductive segments 502, 504, 506, 602 are electrically isolated by a gap 340, which enable any combinations data signals, power and ground to be transmitted through a single multi-conductor via 630. In some examples adjacent data signal carrying conductive segments (for example, conductive segments 502, 506) may be separated by one or more grounded conductive segment (such as conductive segment 504 and/or conductive segment 602).

In the example depicted in FIG. 6B, a multi-conductor via 680 is illustrated having 4 conductive segments 502, 504, 506, 602. The multi-conductor via 680 is configured essentially the same as the multi-conductor via 630, except in that at least two of the conductive segments 502, 506 have a larger sectional area than the two other conductive segments 504, 602. Additionally, the conductive segments 502, 506 having the larger sectional area separate the conductive segments 504, 602 having the smaller sectional area. The larger area conductive segments 502, 506 may have the same sectional area or different sectional area. Similarly, the smaller area conductive segments 504, 602 may have the same sectional area or different sectional area. In one example, the larger area conductive segments 502, 506 are configured to carry ground or power signals, while the smaller area conductive segments 504, 602 are configured to carry data signals. In one example, the conductive segment 504 carries a signal having a polarity opposite to that of the signal carried by the conductive segment 602.

In the example depicted in FIG. 7A, a multi-conductor via 730 is illustrated having 5 conductive segments 502, 504, 506, 602, 702. The conductive segments 502, 504, 506, 602, 702 may have the same sectional area, or one or more of the conductive segments 502, 504, 506, 602, 702 may have a second area different than one or more of the other conductive segments 502, 504, 506, 602, 702.

The multi-conductor via 730 illustrated in FIG. 7A is generally the same as the multi-conductor via 630 described above, except with an additional conductive segment 702 disposed through a common hole 350 formed in the IC device mounting board 108. The first, second, third and fourth conductive segments 502, 504, 506, 602 are coupled to the first, second, third and fourth contact pads 542, 544, 546, 642 by the first, second, third and fourth traces 552, 554, 556, 652 as described with reference to FIGS. 4A and 6A. Similarly, the fifth conductive segment 702 is coupled to a fifth contact pad 742 by a fifth trace 752.

The conductive segments 502, 504, 506, 602, 702 are electrically isolated by a gap 340, which enable any combinations data signals, power and ground to be transmitted through a single multi-conductor via 730. In some examples adjacent data signal carrying conductive segments (for example, conductive segments 502, 506) may be separated by a grounded conductive segment (such as conductive segment 504).

In the example depicted in FIG. 7B, a multi-conductor via 780 is illustrated having 5 conductive segments 502, 504, 506, 602, 702. The multi-conductor via 780 is configured essentially the same as the multi-conductor via 680, except in that at least three of the conductive segments 502, 504, 602 have a smaller sectional area than the two other conductive segments 506, 702. Additionally, at least one of the larger conductive segments 506, 702 having the larger sectional area separate at least two of the conductive segments 502, 504, 602 having the smaller sectional area. The larger area conductive segments 506, 702 may have the same sectional area or different sectional area. Similarly, the smaller area conductive segments 502, 504, 602 may have the same sectional area or different sectional area. In one example, the larger area conductive segments 506, 702 are configured to carry power or ground while the smaller area conductive segments 502, 504, 602 are configured to carry data signals or be electrically floating. In one example, the smaller area conductive segments 502, 504, 602 all carry data signals.

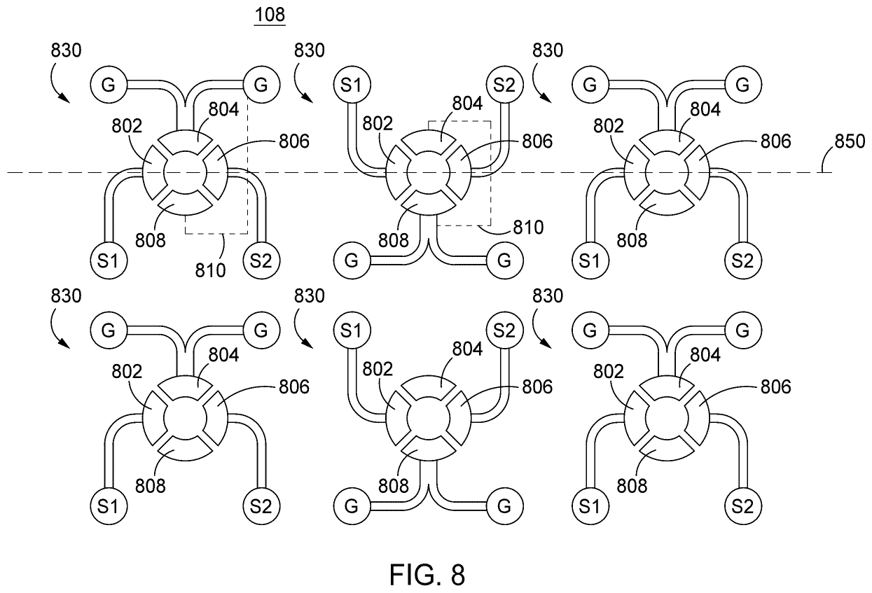

FIG. 8 is a schematic top view of an IC device mounting board 108 illustrating one example of an arrangement of signal transmissions through multi-conductor vias 830. The multi-conductor vias 830 are generally similar to that of the multi-conductor via 630 described above. In FIG. 8, an arrangement of 6 multi-conductor vias 830 are shown, but more or less multi-conductor vias 830 may comprise an arrangement of multi-conductor vias 830 in a given IC device mounting board 108.

Each multi-conductor via 830 includes two data signal carrying conductive segments 802, 806, and at least one grounded conductive segment 804. The first and second data signal carrying conductive segments 802, 806 can also be referred to as the first and third conductive segments, while the grounded conductive segment 804 can also be referred to as the second conductive segment. Each multi-conductor via 830 also includes a fourth conductive segment 808 that may be coupled to ground or be electrically floating. The first and second data signal carrying conductive segments 802, 806 are separated by the third and fourth conductive segments 804, 808.

In the example depicted in FIG. 8, the first data signal carrying conductive segment 802 is coupled to a first contact pad S1, while the second data signal carrying conductive segment 806 is coupled to a second contact pad S2. In one example, the first data signal carrying conductive segment 802 and the first contact pad S1 are configured to carry opposite signals relative to the second data signal carrying conductive segment 806 and the second contact pad S2. Thus, the first data signal carrying conductive segment 802 and the second data signal carrying conductive segment 806 form a differential pair. Similarly, the first and second contact pads S1, S2 also form a differential pair. In FIG. 8, the contact pad S1 carries a signal having a polarity opposite to that of the signal carried by contact pad S2.

The arrangement of the conductive segments comprising the multi-conductor vias 830 is selected such that the data signal carrying conductive segments 802, 806 of the multi-conductor vias 830 are separated by at least one grounded conductive segment and another conductive segment that may be either grounded or electrically floating. The orientation of each data signal carrying conductive segments 802, 806 is the same between the multi-conductor vias 830 aligned in a common row, for example spaced at about 180 degrees apart. The orientation of each data signal carrying conductive segments 802, 806 is also the same between the multi-conductor vias 830 aligned in a common column.

The arrangement of the conductive segments comprising the multi-conductor vias 830 is selected such that the grounded conductive segment is coupled to at least one or both of the contact pads G. Within a common row, the grounded conductive segment coupled to one or both of the contact pads G alternates between the second conductive segment 804 in one multi-conductor via 830 to the fourth conductive segment 808 in the adjacent multi-conductor via 830 within the common row. In some examples, both the second conductive segment 804 and the fourth conductive segment 808 are coupled to the ground contact pads G, for example by jumper traces 810.

In a common row of multi-conductor vias 830, the signal contact pads S1, S2 are located on opposite sides of the multi-conductor vias 830 (for example, relative to an imaginary line 850 passing through the centers of the multi-conductor vias 830 arranged in a common row) from the ground contact pads G. Within a common row, the grounded contact pads G and the signal contact pads S1, S2 of one multi-conductor via 830 are located on opposites sides of the imaginary line 850 relative to the grounded contact pads G and the signal contact pads S1, S2 of the immediately adjacent multi-conductor via 830 located in the same row. For example, the contact pads of first multi-conductor via 830 may have the signal contact pads S1, S2 disposed above the imaginary line 850 (i.e., on a first or top side of the multi-conductor via 830), while the immediately adjacent multi-conductor via(s) 830 located in the same row of multi-conductor vias 830 have the signal contact pads S1, S2 disposed below the imaginary line 850 (i.e., on a second or bottom side of the multi-conductor via 830). Similarly, the ground contact pads G may be disposed below the imaginary line 850 on the first multi-conductor via 830, while the immediately adjacent multi-conductor via(s) 830 located in the same row of multi-conductor vias 830 have the ground contact pads G disposed above the imaginary line 850. In this arrangement, the signal contact pads S1, S2 of adjacent multi-conductor vias 830 are on opposite sides of the vias 830, thus reducing noise and the probability of cost talk between data signals of adjacent vias 830.

Additionally, the arrangement of the signal contact pads S1, S2, and grounded conduct pads G are the same within a column of multi-conductor vias 830. Thus at the intersection bounded by two adjacent rows and two adjacent columns of multi-conductor vias 830, the signal contact pad S1 of one multi-conductor via 830 is diagonally adjacent to the signal contact pad S2 of the adjacent multi-conductor via 830 located in the adjacent row and column of multi-conductor vias 830, while also being separated by at least one grounded contact pad G from the same type of signal pad in both the vertical and horizontal directions. Thus, noise and the probability of cross-talk between signal carrying conductive segments is reduced compared to conventional designs.

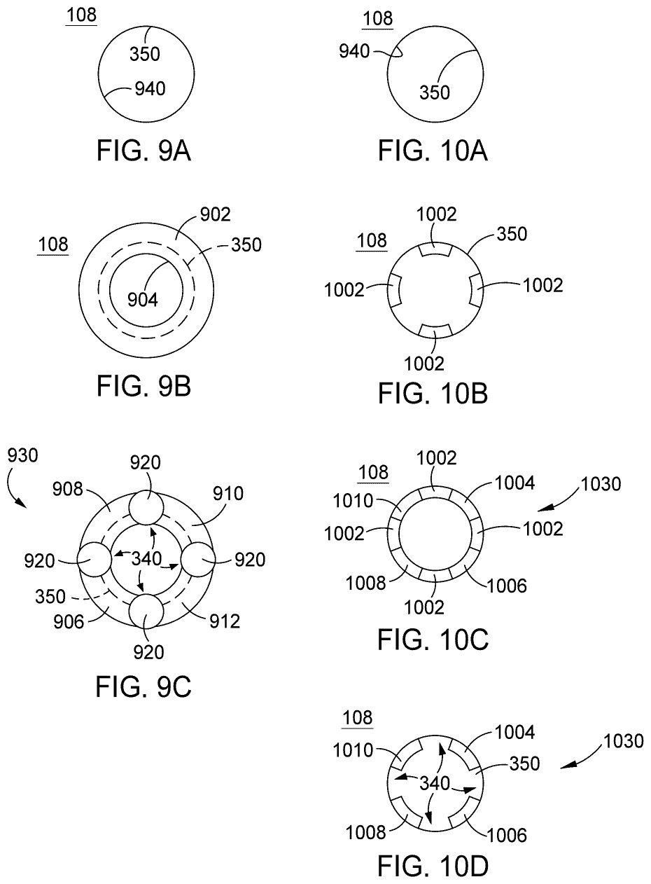

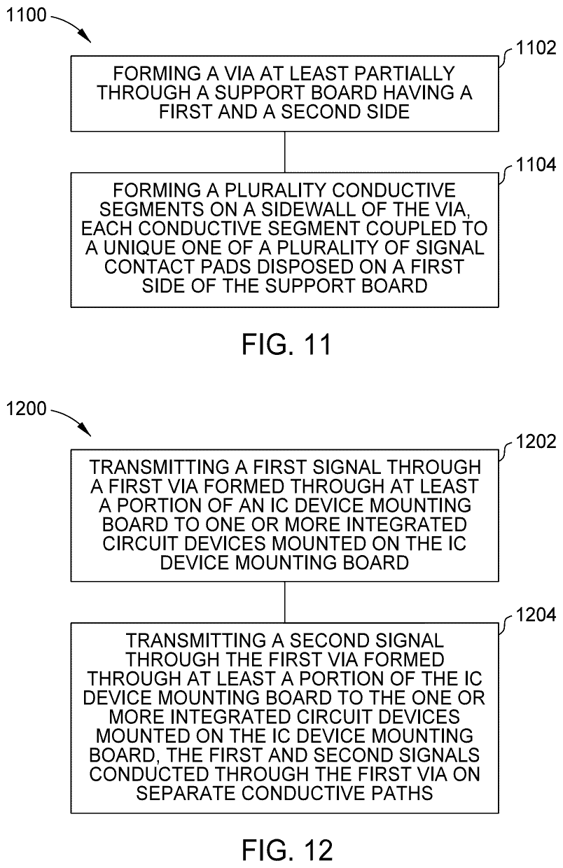

FIGS. 9A-9C are schematic top views of one example of a multi-conductor via 930 during different stages of fabrication an IC device mounting board. FIGS. 10A-10D are schematic top views of another example of a multi-conductor via 1030 during different stages of fabrication an IC device mounting board. FIG. 11 is a flow diagram of a method 1100 for fabricating an IC device mounting board having a multi-conductor via, such as the multi-conductor via 930, 1030, and the like, according to one example. The IC device mounting board may be any of the IC device mounting boards 108 described above, such as an interposer 202, a package substrate 204, and a PCB 104, among others.

The method 1100 for fabricating an IC device mounting board beings at operation 1102 by forming a via (i.e., hole 350) at least partially through a support board 124 of the IC device mounting board 108, as illustrated by FIGS. 9A and 10A. The IC device mounting board 108 has a first surface 330 and a second surface 332. The via may be formed by drilling, milling, laser drilling, etching or another suitable technique. The via includes a sidewall 940.

At operation 1104, a plurality conductive segments are formed on the sidewall 940 of the via. Each conductive segment is coupled to a unique one of a plurality of signal contact pads disposed on a first side of the support board, for example, as shown in the examples depicted in FIG. 2 through FIG. 6. Alternatively, a conductive segment configured to carrier ground or power signals may be coupled to more than one contact pad.

In a first example, operation 1104 may be illustrated by FIGS. 9B and 9C. In FIG. 9B, a conductive material 902 is disposed on the sidewall 940 of the via (hole 350). The conductive material 902 may be copper, tungsten, aluminum, silver, gold or other suitable electrical routing material. The conductive material 902 is then segmented to form individual segments 906, 908, 910, 912. The conductive material 902 may be segmented by drilling, milling, laser drilling, etching or another suitable technique. In the example depicted in FIG. 9C, the conductive material 902 is segmented by drilling holes 920 that form gaps 340 between and completely separate the segments 906, 908, 910, 912. The holes 920 may be formed by any suitable techniques.

In a second example, operation 1104 may be illustrated by FIGS. 10B through 10D. In FIG. 10B, masks 1002 are disposed on the sidewall 940 of the via (hole 350). The masks 1002 may be later removed or may remain as part of the multi-conductor via 1030. If the masks 1002 remain part of the multi-conductor via 1030, the mask 1002 are fabricated from an insulating material that forms the gaps 340 that separate and electrically isolate the conductive segments of the multi-conductor via 1030 from each other.

In the second example, operation 1104 also includes depositing a conductive material 902 on the sidewall 940 of the via that is exposed between the masks 1002, as illustrated in FIG. 10C. In one example, the conductive material 902 is plated on the sidewall 940 of the via between the masks 1002. The mask 1002 also segments the conductive material 902 into separate conductive segments 1004, 1006, 1008, 1010. As discussed above, the masks 1002 may remain between the conductive segments 1004, 1006, 1008, 1010 to form the gaps 340. Alternatively, the masks 1002 may be removed from between the conductive segments 1004, 1006, 1008, 1010, thus leaving the gaps 340 that can remain as air gaps as illustrated in FIG. 10D, or be later filled with an electrically insulating material to maintain the electrical isolation between the conductive segments 1004, 1006, 1008, 1010.

FIG. 12 is a flow diagram of a method 1200 for operating an electronic device that has a multi-conductor via, according to one example. The method 1200 begins at operation 1202 by transmitting a first signal through a first via formed through at least a portion of an IC device mounting board to one or more integrated circuit devices mounted on the IC device mounting board. The first via is a multi-conductor via as described above, with the first signal being transmitted on a first conductive segment of a plurality of conductive segments formed through the first via.

The method 1200 also includes transmitting a second signal through the first via formed through at least a portion of the IC device mounting board to the one or more integrated circuit devices mounted on the IC device mounting board. The second signal is transmit on a second conductive segment of the plurality of conductive segments formed through the first via. Thus, the first and second signals are conducted through the first via on separate conductive paths. That is, the first and second signals are conducted through the first via on separate conductive segments which form the separate conductive paths.

The first and second signals may be both data signals, both power signals, or be both ground signals. The first and second signals may alternatively be a data signal and one of a ground or a power signal; or a ground and power signal.

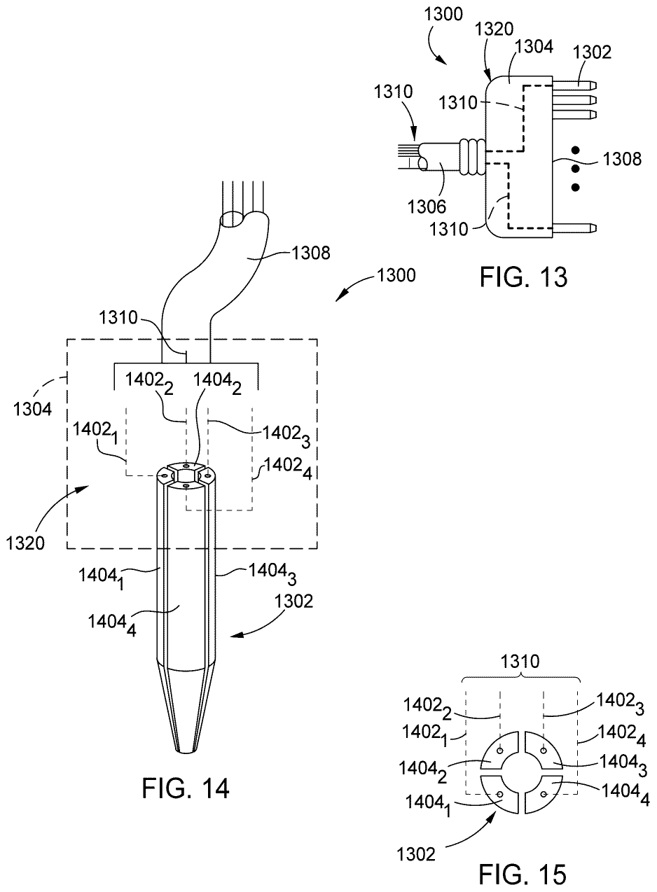

FIG. 13 is a plan view of a cable 1300 having a plug 1320 with pins 1302 configured to mate with multi-conductor vias formed in an IC device mounting board or other device. The plug 1320 includes a body 1304 having a side 1308 from which a plurality pins 1302 extend. A cord 1306 of the cable 1300 includes wires 1310 coupled to the pins 1302 that extends from the body 1304 of the plug 1320, typically from a side of the plug 1320 that is opposite the side 1308.

FIG. 14 is a simplified schematic of the plug 1320 of the cable 1300 illustrating an isometric view of the one of the pins 1302 of the plug 1320 illustrated in FIG. 13. The wires 1310 include two or more conductors (collectively 1402) coupled to each of the pins 1302. The pins 1302 includes two or more elongated conductive pin segments, shown in FIG. 14 as four pin segments 1404₁, 1404₂, 1404₃, 1404₄. Each of the pin segments 1404₁, 1404₂, 1404₃, 1404₄ comprising a single pin 1302 are coupled to separate conductors 1402₁, 1402₂, 1402₃, 1402₄ of the wires 1310, as shown in FIG. 15. Continuing to refer to FIG. 14, the tip of the pin 1302 is tapered to allow the pin 1302 to be inserted into a multi-conductor via (such as the vias 130, 530, 630, 730, 830, 930, 1030, and the like), such that each conductor 1402₁, 1402₂, 1402₃, 1402₄ mate with respective ones of the conductive segments forming the multi-conductive via. Although the pin 1302 illustrated in FIG. 14 has four pin segments 1404, the number of pin segments 1404 may vary to mate with the number of conductive segments forming the multi-conductive via.

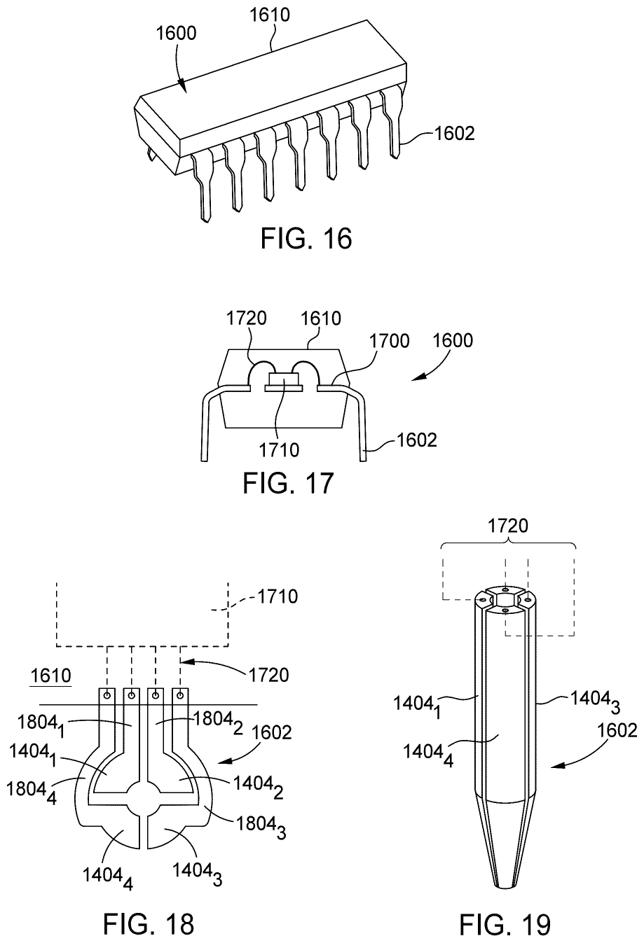

FIGS. 16-17 are isometric and sectional views of a chip package 1600 having a plurality of multi-conductor pins 1602 configured to mate with multi-conductor vias formed in an IC device mounting board or other device. Although the chip package 1600 is generally illustrated as a dual in-line package (DIP) the chip package 1600 is representative of any chip package having one or more communication pins extending therefrom, such as but not limited to other types of through-hole packages, pin grid arrays (PGA), and land grid arrays (LGA), among others.

The chip package 1600 generally include a body 1610 from which the multi-conductor pins 1602. The body 1610 may be an IC die or a protective encapsulant disposed of an IC die. In the example, depicted in FIG. 16, the body 1610 is polymeric enclosure that encapsulates an IC die 1710 disposed on a lead frame 1700. The ends of the lead frame 1710 includes or is connected to the multi-conductor pins 1602. The multi-conductor pins 1602 are coupled to the IC die 1710 via wires 1720 or other suitable electrical connection. Each of the multi-conductor pins 1602 has two or more wires 1720 coupled thereto. The wires 1720 connect the multi-conductor pin 1602 to the functional circuitry of the IC die 1710.

FIG. 18 is a partial top schematic view of one of the multi-conductor pins 1602 of the chip package 1600 illustrated in FIGS. 16-17. The multi-conductor pins 1602 extending from the body 1610 includes a plurality of conductive pin segments. Each pin segment is coupled by a unique metal connector to a unique one of the wires 1720, so that each pin segment can transmit data signals, ground or power to the functional circuitry of the IC die 1710 separately and independently from the other segments comprising a common multi-conductor pin 1602. Although in the example of the multi-conductor pin 1602 depicted in FIG. 18 four conductive pin segments 1404₁, 1404₂, 1404₃, 1404₄ are shown, the number of conductive pin segments may vary from 2 to as many as can be accommodated by the geometry and density the multi-conductor pins 1602.

FIG. 19 is a simplified schematic view of one of the multi-conductor pins of the chip package 1600 illustrated in FIGS. 16-17. The conductive pin segments 1404₁, 1404₂, 1404₃, 1404₄ of the multi-conductor pin 1602 are depicted in FIG. 19 as a defining a substantially circular cross section. However, the conductive pin segments 1404₁, 1404₂, 1404₃, 1404₄ of the multi-conductor pin 1602 may alternatively be arranged in rectangular, triangular, trapezoidal, or other desirable cross sectional profile.

Thus, IC device mounting boards, IC devices and electronic device that include one or more multi-conductor vias have been disclosed herein, along with methods of fabricating and operating the same. The multi-conductor vias leverage separate conductive segments formed within a single via to allow any one of data signal, power and ground to be conducted on any one of the segments. Additionally, any one or more or even all of the conductive segments may be floating. The multi-conductor vias enable fewer vias to be utilized for a given number of contact pads, allowing for increased interconnect density. The space saved by using the multi-conductor via enables the routing of more signals and provides a stronger power supply as metal layers used for power delivery have less holes per power supply pin.

The disclosed technology may be expressed through one or more of the following non-limiting examples.

Example 1. An integrated circuit (IC) device mounting board including: a support board having a first side and a second side; a first via formed through at least a portion of the support board, the first via comprising: a first conductive segment disposed on a sidewall of the first via and; a second conductive segment disposed on the sidewall of the first via, the first and second conductive segments forming separate electrical signal paths through the first via; and a first contact pad formed on the first side of the support board and electrically coupled to the first conductive segment; and a second contact pad formed on the first side of the support board and electrically coupled to the second conductive segment.

Example 2. The IC device mounting board of Example 1 further including: a third conductive segment disposed on the sidewall of the first via, the first, second and third conductive segments forming separate electrical signal paths through the first via; and a third contact pad formed on the first side of the support board and electrically coupled to the third conductive segment.

Example 3. The IC device mounting board of Example 2, wherein the second and third contact pads are configured to conduct data signals, and wherein the first contact pad is configured to be coupled to ground.

Example 4. The IC device mounting board of Example 2 further including: a first trace coupling the first contact pad to the first conductive segment; a second trace coupling the second contact pad to the second conductive segment; and a third trace coupling the third contact pad to the third conductive segment, the first, second and third traces extending linearly outward from the first via.

Example 5. The IC device mounting board of Example 2 further including: a fourth conductive segment disposed on the sidewall of the first via, the first, second, third and fourth conductive segments forming separate electrical signal paths through the first via; and a fourth contact pad formed on the first side of the support board and electrically coupled to the fourth conductive segment.

Example 6. The IC device mounting board of Example 5, wherein the second and fourth contact pads are configured to conduct data signals, and wherein the first and third contact pads are configured to be coupled to ground.

Example 7. The IC device mounting board of Example 6, wherein the first and third conductive segments are separated by the second conductive segment, and wherein the first and third conductive segments are separated by the fourth conductive segment.

Example 8. The IC device mounting board of Example 7, wherein the second and fourth contact pads are configured to conduct differential data signals.

Example 9. The IC device mounting board of Example 1 further including: a second via formed through at least a portion of the support board adjacent the first via, the first via including fifth, sixth, seventh, and eighth conductive segments disposed on a sidewall of the second via, the fifth, sixth, seventh, and eighth conductive segments forming separate electrical signal paths through the second via; a fifth contact pad configured to transmit data signals formed in the first side of the support board and electrically coupled to the fifth conductive segment; a sixth contact pad configured to transmit data signals formed in the first side of the support board and electrically coupled to the sixth conductive segment; a seventh contact pad configured to couple to ground formed in the first side of the support board and electrically coupled to the seventh conductive segment; an eighth contact pad configured to couple to ground formed in the first side of the support board and electrically coupled to the eighth conductive segment, wherein the third and fourth contact pads reside on a first side of an imaginary line passing through the first and second vias while the seventh and eighth contact pads reside on a second side of the imaginary line that is opposite the first side.

Example 10. The IC device mounting board of Example 1 further including: a second via formed through at least a portion of the support board adjacent the first via, the first via including fifth, sixth, seventh, and eighth conductive segments disposed on a sidewall of the second via, the fifth, sixth, seventh, and eighth conductive segments forming separate electrical signal paths through the second via; a fifth contact pad configured to transmit data signals formed in the first side of the support board and electrically coupled to the fifth conductive segment; a sixth contact pad configured to transmit data signals formed in the first side of the support board and electrically coupled to the sixth conductive segment; a seventh contact pad configured to couple to ground formed in the first side of the support board and electrically coupled to the seventh conductive segment; an eighth contact pad configured to couple to ground formed in the first side of the support board and electrically coupled to the eighth conductive segment, wherein the first and fifth contact pads are closer than the second and sixth contact pads, and wherein the first and fifth contact pads are configured to conduct signals of opposite polarity.

Example 11. The IC device mounting board of Example 2, wherein first, second and third contact pads are configured to conduct data signals.

Example 12. The IC device mounting board of Example 2, wherein at least one of first, second and third contact pads are configured to conduct power or be connected to ground.

Example 13. The IC device mounting board of Example 1, further including: a plurality of additional conductive segments disposed on the sidewall of the first via, the first, second and additional conductive segments conductive segments forming separate electrical signal paths through the first via; and a plurality of additional contact pads formed in the first side of the support board, each of the plurality of additional contact pads respectively coupled to a unique one of the plurality of additional conductive segments.

Example 14. The IC device mounting board of Example 1, wherein an air gap spaces the first conductive segment from the second conductive segment.

Example 15. The IC device mounting board of Example 1, further including: an electrically insulating material separating the first conductive segment from the second conductive segment.

Example 16. The IC device mounting board of Example 1, wherein the support board is one of an interposer, a package substrate or a printed circuit board.

Example 17. An integrated circuit (IC) device mounting board including: a support board having a first side and a second side; a plurality of contact pads including Y number of contact pads formed on the first side of the support board; and a plurality of vias having in-via conductors connected to the plurality of contact pads, wherein a number of the plurality of contact pads Y is greater than a number of the plurality of vias.

Example 18. The IC device mounting board of Example 17, wherein the in-via conductors of a first via of the plurality of vias are coupled to at least two contact pads of the plurality of contact pads.

Example 19. The IC device mounting board of Example 17, wherein the in-via conductors of a first via of the plurality of vias are coupled to at least three contact pads of the plurality of contact pads, and wherein at least one of the in-via conductors is configured to couple to ground.

Example 20. The IC device mounting board of Example 17, wherein the in-via conductors of a first via of the plurality of vias are coupled to at least four contact pads of the plurality of contact pads, wherein at least two of the at least four contact pads are configured to couple to ground and at least two of the at least four contact pads are configured to couple to data signals.

Example 21. The IC device mounting board of Example 20, wherein the data signals are differential data signals.

Example 22. The IC device mounting board of Example 17, wherein the support board is one of an interposer, a package substrate or a printed circuit board.

Example 23. An integrated circuit (IC) device including: an integrated circuit (IC) die having at least a first contact pad and a second contact pad disposed on a first surface; and an IC device mounting board having a first via formed in a first side, the IC die mounted on the first side of the IC device mounting board, the IC device mounting board including and a second side, the IC device mounting board including: a first conductive segment disposed on a sidewall of the first via, the first conductive segment coupled to the first contact pad of the IC die and; a second conductive segment disposed on the sidewall of the first via, the second conductive segment coupled to the second contact pad of the IC die.

Example 24. The IC device of Example 23, wherein the IC die further comprise functional circuity configured to receive data signals passing through the first and second conductive segments.

Example 25. The IC device of Example 23 further including: a third conductive segment disposed on the sidewall of the first via, the first, second and third conductive segments forming separate electrical signal paths through the first via; and a third contact pad formed on the first side of the IC device mounting board and electrically coupled to the third conductive segment.

Example 26. The IC device mounting board of Example 25, wherein the second and third contact pads are configured to conduct data signals, and wherein the first contact pad is configured to be coupled to ground.

Example 27. The IC device mounting board of Example 25 further including: a first trace coupling the first contact pad to the first conductive segment; a second trace coupling the second contact pad to the second conductive segment; and a third trace coupling the third contact pad to the third conductive segment, the first, second and third traces extending linearly outward from the first via.

Example 28. The IC device mounting board of Example 25 further including: a fourth conductive segment disposed on the sidewall of the first via, the first, second, third and fourth conductive segments forming separate electrical signal paths through the first via; and a fourth contact pad formed on the first side of the IC device mounting board and electrically coupled to the fourth conductive segment.

Example 29. The IC device mounting board of Example 28, wherein the second and fourth contact pads are configured to conduct data signals, and wherein the first and third contact pads are configured to be coupled to ground.

Example 30. The IC device mounting board of Example 29, wherein the first and third conductive segments are separated by the second conductive segment, and wherein the first and third conductive segments are separated by fourth conductive segment.

Example 31. The IC device mounting board of Example 30, wherein the second and fourth contact pads are configured to conduct differential data signals.

Example 32. The IC device of Example 23 further including: a second via formed through at least a portion of the IC device mounting board adjacent the first via, the first via including fifth, sixth, seventh, and eighth conductive segments disposed on a sidewall of the second via, the fifth, sixth, seventh, and eighth conductive segments forming separate electrical signal paths through the second via; a fifth contact pad configured to transmit data signals formed in the first side of the IC device mounting board and electrically coupled to the fifth conductive segment; a sixth contact pad configured to transmit data signals formed in the first side of the IC device mounting board and electrically coupled to the sixth conductive segment; a seventh contact pad configured to couple to ground formed in the first side of the IC device mounting board and electrically coupled to the seventh conductive segment; an eighth contact pad configured to couple to ground formed in the first side of the IC device mounting board and electrically coupled to the eighth conductive segment, wherein the third and fourth contact pads reside on a first side of an imaginary line passing through the first and second vias while the seventh and eighth contact pads reside on a second side of the imaginary line that is opposite the first side.

Example 33. The IC device of Example 23 further including: a second via formed through at least a portion of the IC device mounting board adjacent the first via, the first via including fifth, sixth, seventh, and eighth conductive segments disposed on a sidewall of the second via, the fifth, sixth, seventh, and eighth conductive segments forming separate electrical signal paths through the second via; a fifth contact pad configured to transmit data signals formed in the first side of the IC device mounting board and electrically coupled to the fifth conductive segment; a sixth contact pad configured to transmit data signals formed in the first side of the IC device mounting board and electrically coupled to the sixth conductive segment; a seventh contact pad configured to couple to ground formed in the first side of the IC device mounting board and electrically coupled to the seventh conductive segment; an eighth contact pad configured to couple to ground formed in the first side of the IC device mounting board and electrically coupled to the eighth conductive segment, wherein the first and fifth contact pads are closer than the second and sixth contact pads, and wherein the first and fifth contact pads are configured to conduct signals of opposite polarity.

Example 34. The IC device of Example 25, wherein first, second and third contact pads are configured to conduct data signals.

Example 35. The IC device mounting board of Example 25, wherein at least one of first, second and third contact pads are configured to conduct power or be connected to ground.

Example 36. The IC device of Example 23 further including: a plurality of additional conductive segments disposed on the sidewall of the first via, the first, second and additional conductive segments conductive segments forming separate electrical signal paths through the first via; and a plurality of additional contact pads formed in the first side of the IC device mounting board, each of the plurality of additional contact pads respectively coupled to a unique one of the plurality of additional conductive segments.

Example 37. The IC device of Example 23, wherein an air gap spaces the first conductive segment from the second conductive segment.

Example 38. The IC device of Example 23 further including: an electrically insulating material separating the first conductive segment from the second conductive segment.

Example 39. The IC device of Example 23, wherein the IC device mounting board is one of an interposer, a package substrate or a printed circuit board.

Example 40. An integrated circuit (IC) device including: an integrated circuit (IC) die having at least a first contact pad and a second contact pad disposed on a first surface; and an IC device mounting board having a first via formed in a first side, the IC die mounted on the first side of the IC device mounting board, the IC device mounting board including and a second side, the IC device mounting board including: a support board having a first side and a second side; a plurality of contact pads including Y number of contact pads formed on the first side of the support board; and a plurality of vias formed in the support board, wherein a number of the plurality of contact pads Y is greater than a number of the plurality of vias, and at least a first contact pad and a second contact pad of the support board are coupled to the first and second contact pads of the IC die by separate in-via conductors disposed in a first via of the plurality of vias.

Example 41. The IC device of Example 40, wherein the in-via conductors disposed in the first via are coupled to at least three contact pads of the plurality of contact pads, and wherein at least one of the in-via conductors is configured to couple to ground.

Example 42. The IC device of Example 40, wherein the in-via conductors of the first via are coupled to at least four contact pads of the plurality of contact pads, wherein at least two of the at least four contact pads are configured to couple to ground and at least two of the at least four contact pads are configured to couple to data signals.

Example 43. The IC device of Example 42, wherein the data signals are differential data signals.

Example 44. The IC device of Example 40, wherein the support board is one of an interposer, a package substrate or a printed circuit board.

Example 45. A method for fabricating an integrated circuit (IC) device mounting board, the method including: forming a via at least partially through a support board having a first side and a second side; and forming a plurality conductive segments on a sidewall of the via, each conductive segment coupled to a unique one of a plurality of signal contact pads disposed on a first side of the support board.

Example 46. The method of Example 45, wherein forming the plurality conductive segments on the sidewall of the via further includes: depositing a conductive material on the sidewall of the via; and removing portions of the conductive material deposited on the sidewall of the via to form the plurality conductive segments.

Example 47. The method of Example 45, wherein forming the plurality conductive segments on the sidewall of the via further includes: depositing strips of conductive material on the sidewall of the via to form the plurality conductive segments.

Example 48. The method of Example 47, wherein depositing strips of conductive material on the sidewall of the via further includes: masking portions of the sidewall of the via; and depositing the strips of conductive material on the sidewall of the via between the masked portions of the sidewall to form the plurality conductive segments.

Example 49. A method for operating an integrated circuit (IC) device, the method including: transmitting a first signal through a first via formed through at least a portion of an IC device mounting board to one or more integrated circuit devices mounted on the IC device mounting board; and transmitting a second signal through the first via formed through at least a portion of the IC device mounting board to the one or more integrated circuit devices mounted on the IC device mounting board, the first and second signals conducted through the first via on separate conductive paths.

Example 50. The method of Example 49, wherein the first and second signals have different polarities.

Example 51. The method of Example 49 further including: transmitting a fourth signal through a second via formed through at least a portion of the IC device mounting board to the one or more integrated circuit devices mounted on the IC device mounting board; and transmitting a fifth signal through the second via formed through at least a portion of the IC device mounting board to the one or more integrated circuit devices mounted on the IC device mounting board, the fourth and fifth signals having different polarities and conducted through the second via on separate conductive paths, wherein a first conductor routing the first signal through the first via is closer to a second conductor routing the third signal through the second via than a third conductor routing the third signal through the first via, wherein the first and third signals have different polarities.

Example 52. A multi-die stack including a first IC die stacked on a second IC die, the first and second IC dies having a multi-conductor via formed therethrough, the multi-conductor via having a first conductive segment electrically coupled to functional circuitry of the first IC die and a second conductive segment electrically coupled to functional circuitry of the second IC die.

Example 53. The multi-die stack of Example 52, wherein the functional circuitry of the first and second IC dies are configured as memory circuitry.

Example 54. The multi-die stack of Example 52, wherein the second conductive segment is coupled to the functional circuitry of the second IC die via routing formed in a hybrid bonding layer that electrically and mechanically couples the first and second IC dies.

Example 55. A chip package including an IC die and a plurality of multi-conductor pins coupled to functional circuitry of the IC die, at least a first multi-conductor pin of the multi-conductor pins including a plurality of pin segments configured to separately couple to functional circuitry of the IC die relative to the other pin segments of the first multi-conductor pin.

While the foregoing is directed to specific examples, other and further examples may be devised without departing from the basic scope thereof, and the scope thereof is determined by the claims that follow.

What is claimed is:

1. An integrated circuit (IC) device comprising:
an integrated circuit (IC) die having at least a first contact pad and a second contact pad disposed on a first surface; and
an IC device mounting board having a first via formed in a first side, the IC die mounted on the first side of the IC device mounting board, the IC device mounting board comprising:
a first conductive segment disposed on a sidewall of the first via, the first conductive segment coupled to the first contact pad of the IC die: and
a second conductive segment disposed on the sidewall of the first via, the second conductive segment coupled to the second contact pad of the IC die.

2. The IC device of claim 1, wherein the IC die further comprise functional circuity configured to receive data signals passing through the first and second conductive segments.

3. The IC device of claim 1 further comprising:
a third conductive segment disposed on the sidewall of the first via, the first, second and third conductive segments forming separate electrical signal paths through the first via; and
a third contact pad formed on the first side of the IC device mounting board and electrically coupled to the third conductive segment.

4. The IC device mounting board of claim 3, wherein the second and third contact pads are configured to conduct data signals, and wherein the first contact pad is configured to be coupled to ground.

5. The IC device mounting board of claim 3 further comprising:
a first trace coupling the first contact pad to the first conductive segment;
a second trace coupling the second contact pad to the second conductive segment; and
a third trace coupling the third contact pad to the third conductive segment, the first, second and third traces extending linearly outward from the first via.

6. The IC device mounting board of claim 3 further comprising:
a fourth conductive segment disposed on the sidewall of the first via, the first, second, third and fourth conductive segments forming separate electrical signal paths through the first via; and
a fourth contact pad formed on the first side of the IC device mounting board and electrically coupled to the fourth conductive segment.

7. The IC device mounting board of claim 6, wherein the second and fourth contact pads are configured to conduct data signals, and wherein the first and third contact pads are configured to be coupled to ground, wherein the first and third conductive segments are separated by the second and fourth conductive segments.

8. The IC device mounting board of claim 7,
wherein the first and third conductive segments are separated by the second conductive segment;
wherein the first and third conductive segments are separated by the fourth conductive segment; and
wherein the second and fourth contact pads are configured to conduct differential data signals.

9. The IC device of claim 3, wherein first, second and third contact pads are configured to conduct data signals.

10. The IC device mounting board of claim 3, wherein at least one of first, second and third contact pads are configured to conduct power or be connected to ground.

11. The IC device of claim 1 further comprising:
a plurality of additional conductive segments disposed on the sidewall of the first via, the plurality of additional conductive segments including the first, second and additional conductive segments forming separate electrical signal paths through the first via; and
a plurality of additional contact pads formed in the first side of the IC device mounting board, each of the plurality of additional contact pads respectively coupled to a unique one of the plurality of additional conductive segments.

12. The IC device of claim 1, wherein an air gap or an electrically insulating material spaces the first conductive segment from the second conductive segment.

13. The IC device of claim 1, wherein the IC device mounting board is one of an interposer, a package substrate or a printed circuit board.

14. An integrated circuit (IC) device comprising:
an integrated circuit (IC) die having at least a first contact pad and a second contact pad disposed on a first surface; and
an IC device mounting board having a first via formed in a first side, the IC die mounted on the first side of the IC device mounting board, the IC device mounting board comprising and a second side, the IC device mounting board comprising:
a support board having a first side and a second side;
a plurality of contact pads including Y number of contact pads formed on the first side of the support board; and
a plurality of vias formed in the support board, wherein the Y number of plurality of contact pads is greater than a number of the plurality of vias, and at least a first contact pad and a second contact pad of the support board are coupled to the first and second contact pads of the IC die by separate in-via conductors disposed in a first via of the plurality of vias.

15. The IC device of claim 14, wherein the in-via conductors disposed in the first via are coupled to at least three contact pads of the plurality of contact pads, and wherein at least one of the in-via conductors is configured to couple to ground.

16. The IC device of claim 14, wherein the in-via conductors of the first via are coupled to at least four contact pads of the plurality of contact pads, wherein at least two of the at least four contact pads are configured to couple to ground and at least two of the at least four contact pads are configured to couple to data signals.

17. The IC device of claim 16, wherein the data signals are differential data signals.

18. The IC device of claim 14, wherein the support board is one of an interposer, a package substrate or a printed circuit board.

19. The IC device of claim 18, wherein the IC die includes functional circuitry coupled to the first and second contact pads, the functional circuitry comprising computer processing circuity or graphics processing circuitry, the functional circuitry communicating with other IC dies mounted to remote printed circuit boards within a server.

20. A method for operating an integrated circuit (IC) device, the method comprising:
transmitting a first signal through a first via formed through at least a portion of an IC device mounting board to one or more integrated circuit devices mounted on the IC device mounting board; and
transmitting a second signal through the first via formed through at least a portion of the IC device mounting board to the one or more integrated circuit devices mounted on the IC device mounting board, the first and second signals are conducted through the first via on separate conductive paths.
